(19) United States
(12) Patent Application Publication
(10) Pub. No.: US 2011/0259421 A1
(43) Pub. Date: Oct. 27, 2011

(54) PHOTOVOLTAIC MODULE HAVING CONCENTRATOR

(75) Inventor: Te-Yuan Chung, Jhongli (TW)

(73) Assignee: NATIONAL CENTRAL UNIVERSITY, Taoyuan (TW)

(21) Appl. No.: 13/095,197

(22) Filed: Apr. 27, 2011

(30) Foreign Application Priority Data
Apr. 27, 2010 (TW) 099113318

(51) Int. Cl. H01L 31/0232

(52) U.S. Cl. 136/259

(57) ABSTRACT

A photovoltaic module with reduced size is provided. The photovoltaic module includes two wedged concentrator components and a solar cell structure. The first wedged concentrator component is positioned on the second wedged concentrator component. The solar cell structure is mounted on a quadrilateral lateral surface of the first wedged concentrator component for receiving light from the first wedged concentrator component through the quadrilateral lateral surface. The wedge structure of the concentrator components causes total internal reflection of the light on a top surface of the first wedged concentrator component when the light travels within the first wedged concentrator component from a bottom surface to the quadrilateral lateral surface. A diffractive optics element is provided in the second wedged concentrator component to contribute the total internal reflection in the first wedged concentrator component.

### FIELD OF THE INVENTION

The present invention relates to a photovoltaic module having a concentrator, and more particularly to a photovoltaic module having a wedged concentrator with reduced size and high concentration ratio.

### BACKGROUND OF THE INVENTION

In recent years, renewable resource attracts great investment and attention due to the overuse of non-renewable resource such as fossil fuel and environmental protection issue. Solar energy is important renewable resource which is clean, safe and abundant, compared with the polluting fuel and hazardous nuclear energy. Solar cells (photovoltaic cells) generate electrical power by converting solar radiation into direct current electricity. The spectrum of sunlight includes visible light, ultraviolet light (wavelength<400 nm) and infrared light (wavelength>700 nm). For this wavelength range, materials presently used for photovoltaics include silicon material such as monocrystalline silicon, polycrystalline silicon and amorphous silicon, which have better photovoltaic effect. Among the silicon materials, monocrystalline has the best conversion efficiency but the highest cost. On the other hand, the polycrystalline silicon is of less efficiency, but is less expensive to produce in bulk.

A solar cell may include a PN junction with a large surface area. The generation of electric current happens inside the depletion zone of the PN junction. When a photon of light, carrying energy higher than the energy gap required to activate an atom from the valence band to the conduction band, is absorbed by an atom in the N-type silicon, it will dislodge an electron to create a free electron and a hole. The free electrons and holes flow between the cathode and the anode to provide the electric current.

The performance of the solar cell depends on the photovoltaic efficiency of the solar cell. With the development of various semiconductor processes, the efficiency of the solar cells is much improved. For example, III-V material such as GaAs material has some electronic and material properties which are superior to those of silicon. Furthermore, GaAs material has direct band gap and can absorb the sunlight photons more efficiently. Hence, great emphasis is put on high efficiency GaAs solar cell. For cost consideration, thin-film solar cells are also rapidly growing. Furthermore, solar tracker systems are developed to assist the solar cells to automatically follow the sun during the course of a day and throughout the seasons of the year so as to generate more energy than conventional fixed approaches.

Other than the above-mentioned approaches, how to collect more sunlight is another issue to increase the energy output of the solar cells or the photovoltaic cells. Since the solar cells can only receive incident light with limited angle of incidence, the photovoltaic module is usually designed as a large area panel and a solar cell array is arranged in the panel to receive most of the nearly normal incident light. In other to reduce the size of the panel and the quantity of the solar cells, a concentrator is provided in the photovoltaic module to collect non-normal incident light to increase the efficiency. Several documents or patents such as US 2007/0095385 A1, TWM361103, TWM350025 and TWM360983 proposed several structures of the photovoltaic modules.

Please refer to FIG. 1, a schematic diagram illustrating the structure of a conventional photovoltaic module. The photovoltaic module 1 includes a concentrating structure 10 and a solar cell array 11. The concentrating structure 10 employs a condensing lens 12 to refract and focus light. The central incident light is focused on the main area A, while the other incident light is reflected and compensated by a plurality of compensating elements 13 to reach the main area A. Therefore, the concentrating effect is enhanced. The solar cell array 11 located at the main area A under the condensing lens 12 receives the focused, refracted or reflected light and performs photovoltaic conversion to generate electrical power.

The above-described concentrating structure 10 can change the light paths of the incident light to allow the incident light to reach limited area. Hence, the size or number of the solar cells of the solar cell array 11 can be reduced. The photovoltaic module 1, however, has considerably large size due to the thick concentrating structure 10. Furthermore, the concentrating effect is also affected when the incident direction of the light is gradually changed during the sun's movement. Such concentrating structure 10 cannot collect and transmit most sunlight to the main area A all the time.

Therefore, there is a need of providing a photovoltaic module with reduced size and high concentration ratio in order to obviate the drawbacks encountered from the prior art.

### SUMMARY OF THE INVENTION

In accordance with an aspect of the present invention, there is provided a photovoltaic module. The photovoltaic module includes two wedged concentrator components and a solar cell structure. The first wedged concentrator component has a first top surface and a first bottom surface arranged unparallel with each other, while the second wedged concentrator component has a second top surface and a second bottom surface arranged unparallel with each other. The first wedged concentrator component is positioned on the second wedged concentrator component by placing the first bottom surface on the second top surface. The solar cell structure is mounted on a quadrilateral lateral surface of the first wedged concentrator component for receiving light from the first wedged concentrator component through the quadrilateral lateral surface. At first, the light enters and leaves the first wedged concentrator component through the first top surface and the first bottom surface, respectively. Then, the light enters and leaves the second wedged concentrator component through the second top surface. The light enters the first wedged concentrator component again through the first bottom surface, and leaves the first wedged concentrator component through the quadrilateral lateral surface. Total internal reflection occurs on at least the first top surface when the light travels within the first wedged concentrator component from the first bottom surface to the quadrilateral lateral surface. At last, the light is received by the solar cell structure mounted on the quadrilateral lateral surface of the first wedged concentrator component.

In accordance with another aspect of the present invention, there is provided another photovoltaic module. The photovoltaic module includes two wedged concentrator components and a solar cell structure. The first wedged concentrator component has a first top surface and a first bottom surface arranged unparallel with each other, while the second wedged concentrator component has a second top surface and a second bottom surface arranged unparallel with each other. The second wedged concentrator component is located beside the first wedged concentrator component, and the second top surface is adjacent to a first quadrilateral lateral surface of the first wedged concentrator component. The solar cell structure is mounted on a second quadrilateral lateral surface of the second wedged concentrator component for receiving light from the second wedged concentrator component through the second quadrilateral lateral surface. At first, the light enters and leaves the first wedged concentrator component through the first top surface and the first quadrilateral lateral surface, respectively. Then, the light enters and leaves the second wedged concentrator component through the second top surface and the second quadrilateral lateral surface, respectively. At last, the light is received by the solar cell structure mounted on the second quadrilateral lateral surface of the second wedged concentrator component.

### BRIEF DESCRIPTION OF THE DRAWINGS

The above contents of the present invention will become more readily apparent to those ordinarily skilled in the art after reviewing the following detailed description and accompanying drawings, in which:

FIG. 1 is a schematic diagram illustrating the structure of a conventional photovoltaic module;

FIG. 2A is a perspective view illustrating a first embodiment of a photovoltaic module according to the present invention;

FIG. 2B is a side view of the photovoltaic module of FIG. 2A;

FIG. 3A is a perspective view illustrating a second embodiment of a photovoltaic module according to the present invention;

FIG. 3B is a side view of the photovoltaic module of FIG. 3A;

FIG. 3C is a top view of the photovoltaic module of FIG. 3A illustrating the light path;

FIG. 4 is a perspective view illustrating a third embodiment of a photovoltaic module according to the present invention; and

FIG. 5 is a perspective view illustrating a photovoltaic module obtained by modifying the photovoltaic module of FIG. 4.

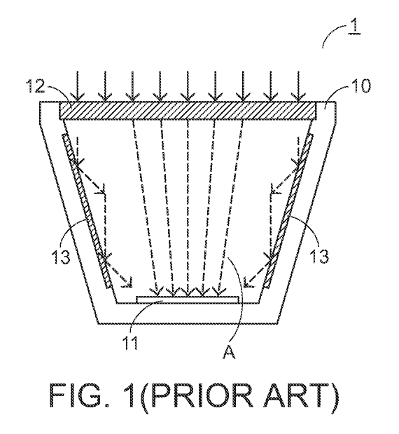

### DETAILED DESCRIPTION OF THE PREFERRED EMBODIMENT

The present invention will now be described more specifically with reference to the following embodiments. It is to be noted that the following descriptions of preferred embodiments of this invention are presented herein for purpose of illustration and description only. It is not intended to be exhaustive or to be limited to the precise form disclosed.

From above description, the solar cell (photovoltaic cell) usually works together with concentrator(s) to enhance light-collecting efficiency and conversion efficiency. According to the conventional design, the concentrator usually faces toward the same direction as the solar cell (photovoltaic cell). In other words, the main incident direction of the light to be collected is substantially vertical to the light-receiving surface of the solar cell. It is called as “coaxial”. The light entering the concentrator is reflected or focused so as to be transmitted to the designation area. To achieve the desired light-collecting efficiency, the size or the thickness of the concentrator cannot be reduced due to the concentrator.

According to the present invention, the solar cell is located on the lateral surface of the concentrator. In other words, the concentrator does not face toward the same direction as the solar cell. The light entering the concentrator is reflected to pass the lateral surface. In addition to enhancing the light-collecting efficiency, the size or thickness of the photovoltaic cell may be reduced. The special structure of the concentrator is illustrated as follows.

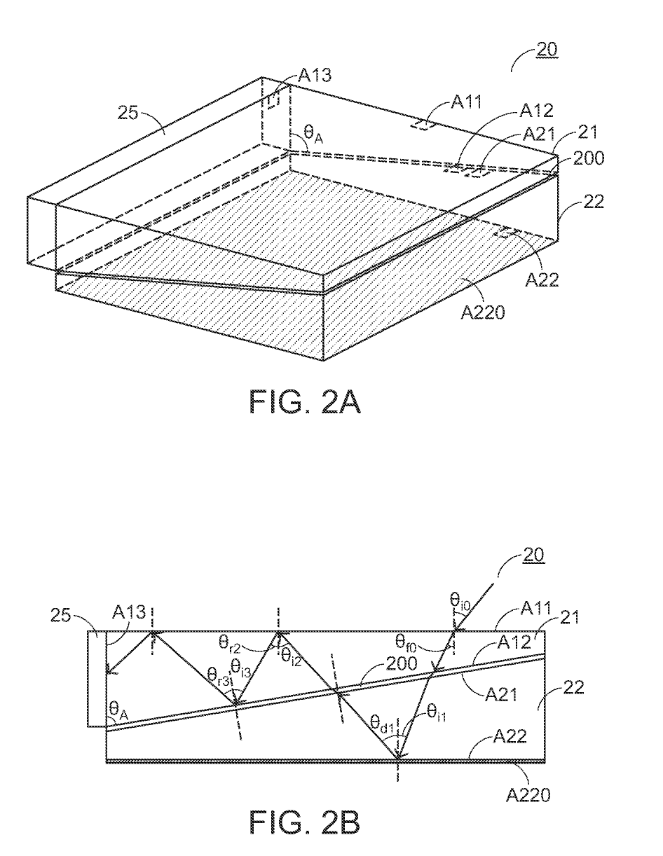

Please refer to FIG. 2A, a perspective view illustrating a first embodiment of a photovoltaic module according to the present invention. The photovoltaic module 20 includes two wedged concentrator components 21 and 22. In an embodiment, the first wedged concentrator component 21 includes a top surface A11 and a bottom slant surface A12 opposite to each other in an unparallel manner and lateral surfaces, while the second wedged concentrator component 22 includes a top slant surface A21 and a bottom surface A22 opposite to each other in an unparallel manner and lateral surfaces. The first wedged concentrator component 21 is positioned on the second wedged concentrator component 22 by placing the bottom slant surface A12 of the first wedged concentrator component 21 on the top slant surface A21 of the second wedged concentrator component 22. There is a gap 200 formed between the bottom slant surface A12 and the top slant surface A21.

The wedged concentrator components 21 and 22 are made of transparent material such as glass. A diffractive optics element A220 is disposed on the bottom surface A22 of the second wedged concentrator component 22. The surfaces of the wedged concentrator components 21 and 22 are coated or covered with high reflectance material except for the light path, i.e. the top surface A11, the bottom slant surface A12, the quadrilateral lateral surface A13 and the top slant surface A21. Although the transparent top surface A11 of the first wedged concentrator component 21 is capable of receiving the incident light, scatter phenomenon always occurs. To avoid possible reflection by the top surface A11, an anti-reflective film (not shown) is optionally applied to the outside of the top surface A11 to reduce photon loss due to reflection.

The photovoltaic module 20 further includes a solar cell structure 25 mounted on the lateral surface A13 of the first wedged concentrator component 21 for performing photovoltaic conversion. The solar cell structure 25 includes at least a solar cell. The design, property or function of the solar cell is similar to the conventional photovoltaic module. For example, monocrystalline silicon, polycrystalline silicon, amorphous silicon, or GaAs solar cell is applicable. The quantity of the solar cells is determined according to the size of the lateral surface A13 of the first wedged concentrator component 21.

In this embodiment, the top surface A11 faces toward and receives the sunlight. The incident light will be refracted or reflected by the surfaces of the wedged concentrator components 21 and 22, and thus reach the lateral surface A13. Then, the solar cell structure 25 receives the collected light and performs photovoltaic conversion to generate electrical power. It is to be noted that reflection and refraction of the light occur based on the dimension, angle between surfaces or material of the wedged concentrator components 21 and 22. In this embodiment, the related surfaces are smooth surfaces without curvature.

As described above, the wedged concentrator component has two unparallel surfaces to direct and condense the light therebetween, e.g. the top surface A11 and the bottom slant surface A12 of the first wedged concentrator component 21. In particular, there is an acute angle θ_{A} between the lateral surface A13 and the bottom slant surface A12. The top surface A11 may be perpendicular to the four lateral surfaces, but not limited to this condition. The second wedged concentrator component 22 has the similar structure. In this embodiment, the two wedged concentrator components 21 and 22 have similar dimension, but are not limited to this condition. The condensing effect of the photovoltaic module 20 depends on the acute angle θ_{A} between the lateral surface A13 and the bottom slant surface A12.

Please refer to FIG. 2B, a side view of the photovoltaic module 20 of FIG. 2A. The light with angle of incidence θᵢ₀ enters the first wedged concentrator component 21 through the top surface A11. The light direction is changed and the angle of refraction is θ_{f0}. Then, the refracted light reaches the bottom slant surface A12. Since the gap 200 between the bottom slant surface A12 and the top slant surface A21 is usually filled with gas or other medium with low index of refraction, the light will pass through the bottom slant surface A12 and the top slant surface A21 to enter the second wedged concentrator component 22 and reach the bottom surface A22 with an angle of incidence θᵢ₁. The light path in the first wedged concentrator component 21 is parallel to that in the second wedged concentrator component 22 under the condition that the two wedged concentrator components 21 and 22 are made of the same material. The angle of incidence θᵢ₁ is equivalent to the angle of refraction θ_{f0} when the top surface A11 and the bottom surface A22 are parallel with each other.

In an embodiment, the diffractive optics element A220 on the bottom surface A22 is a periodic grating structure in micrometer dimension with high reflectance. The periodic grating structure may have rectangular or triangular profile, and the spacing of the periodic grating structure depends on the wavelength of the light. Most of the light emitted to the periodic grating structure is diffracted with angle larger than the angle of reflection. That is, the periodic grating structure can increase the angle of reflection. For example, a portion of the light is sent back to the top slant surface A21 with an angle θ_{d1} deviating from the normal to the bottom surface A22. The angle θ_{d1} is greater than the angle of incidence θᵢ₁. Then, the light sequentially passes through the top slant surface A21, the gap 200 and the bottom slant surface A12 with refraction. The light reaches the top surface A11 with an angle of incidence θᵢ₂. As explained above, the light path in the second wedged concentrator component 22 is parallel to that in the first wedged concentrator component 21, and the angle of incidence θᵢ₂ is equivalent to the angle θ_{d1} which is greater than the angle of refraction θ_{f0}.

In this embodiment, the angle of incidence θᵢ₂ is greater than the critical angle for the boundary between the top surface A11 and the surrounding gas (or other specific medium with low index of refraction) and total internal reflection happens. Due to the wedge structure of the concentrator component 21, the next angle of incidence is greater than the previous angle of incidence along the light path, i.e. θᵢ₂=θᵣ₂<θᵢ₃=θᵣ₃< . . . Therefore, the angle of incidence is always greater than the critical angle to ensure total internal reflection. After several total internal reflections, the light is successfully collected to the lateral surface A13 so that the solar cell structure 25 may receive the most light photons.

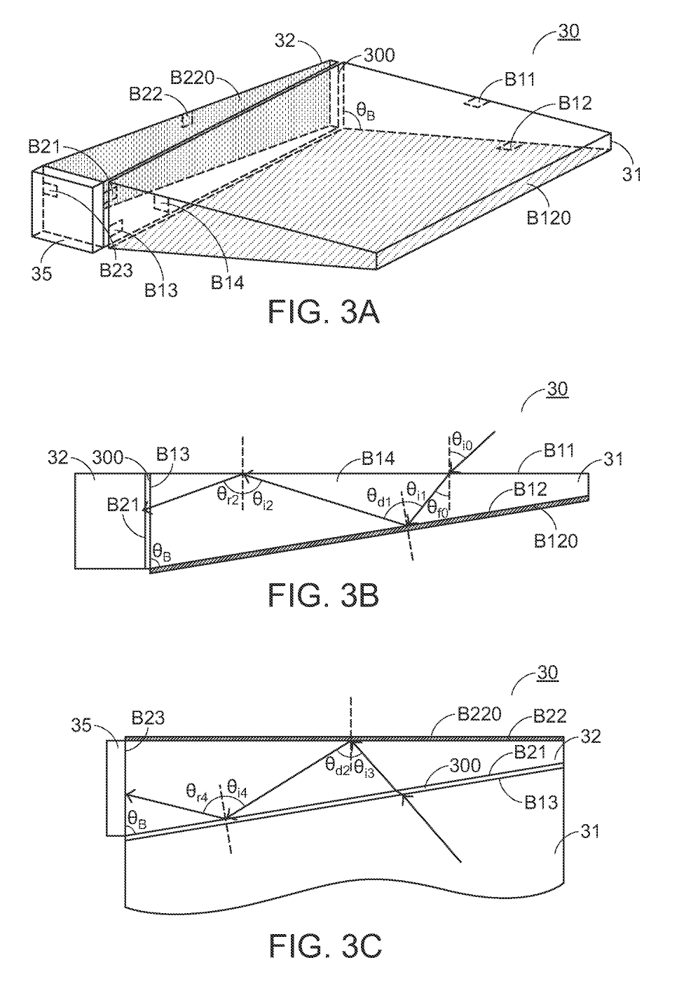

Please refer to FIG. 3A, a perspective view illustrating a second embodiment of a photovoltaic module according to the present invention. The photovoltaic module 30 includes two wedged concentrator components 31 and 32. In this embodiment, the first wedged concentrator component 31 includes a top surface B11 and a bottom surface B12 opposite to each other in unparallel manner, while the second wedged concentrator component 32 includes a top surface B21 and a bottom slant surface B22 opposite to each other in unparallel manner. The second wedged concentrator component 32 is laid on one lateral side and positioned beside the first wedged concentrator component 31. The top surface B21 is made to be adjacent to a quadrilateral lateral surface B13 of the first wedged concentrator component 31. There is a gap 300 formed between the top surface B21 and the lateral surface B13.

As described with reference to FIG. 2, the wedged concentrator components 31 and 32 may be made of transparent material such as glass. Furthermore, in this embodiment, diffractive optics elements B120 and B220 are disposed on the bottom slant surfaces B12 and B22 of the first wedged concentrator component 31 and the second wedged concentrator component 32, respectively. The surfaces of the wedged concentrator components 31 and 32 are coated or covered with high reflectance material except for the light path, i.e. the top surface B11, the quadrilateral lateral surface B13, the top surface B21 and the quadrilateral lateral surface B23. An anti-reflective film (not shown) is optionally applied to the outside of the top surface B11 to reduce reflection and scatter phenomenon.

The photovoltaic module 30 further includes a solar cell structure 30 mounted on the quadrilateral lateral surface B23 of the second wedged concentrator component 32 for performing photovoltaic conversion. The solar cell structure 35 includes at least a solar cell. The design, property or function of the solar cell is similar to the conventional photovoltaic module. For example, monocrystalline silicon, polycrystalline silicon, amorphous silicon, or GaAs solar cell is applicable. The quantity of the solar cells is determined according to the size of the quadrilateral lateral surface B23 of the second wedged concentrator component 32. Compared to the photovoltaic module 20 in the first embodiment, the present photovoltaic module 30 having lateral-to-top combination of the wedged concentrator components 31 and 32 has better condensing efficiency. Therefore, the area of the solar cell structure 35 or the quantity of the solar cells can be further reduced.

In this embodiment, the top surface B11 faces toward and receives the sunlight. The incident light will be refracted or reflected by the surfaces of the wedged concentrator components 31 and 32, and thus reach the lateral surface B23. Then, the solar cell structure 35 receives the collected light and performs photovoltaic conversion to generate electrical power. The design of the unparallel surfaces B11 and B12 and the unparallel surfaces B21 and B22 may direct and restrict the light in the wedged concentrator components 31 and 32 with very little loss. In this embodiment, there is an acute angle θ_{B} between the lateral surface B13 and the bottom surface B12. The top surface B11 may be perpendicular to the four lateral surfaces, but not limited to this condition. The second wedged concentrator component 32 has the similar structure. There is an acute angle, may be equivalent to the acute angle θ_{B}, between the lateral surface B23 and the top surface B21. The angle between the lateral surface B13 and another lateral surface B14 may be supplementary angle of angle θ_{B}. The condensing effect of the photovoltaic module 30 depends on the acute angle θ_{B}.

Please refer to FIG. 3B, a side view of the photovoltaic module 30 of FIG. 3A. The light with angle of incidence θᵢ₀, greater than that described in the first embodiment, enters the first wedged concentrator component 31 through the top surface B11. The light direction is changed and the angle of refraction is θ_{f0}. Then, the refracted light reaches the bottom surface B12. In this embodiment, most of the light emitted to the bottom surface B12 is diffracted by the diffractive optics element B120 with angle larger than the angle of reflection. That is, the diffractive optics element B120 such as periodic grating structure can increase the angle of reflection. For example, a portion of the light is sent back to the top surface B11 with an angle θ_{d1} deviating from the normal to the bottom surface B12. The angle θ_{d1} is greater than the angle of incidence θᵢ₁. The light reaches the top surface B11 with an angle of incidence θᵢ₂. In this embodiment, the angle of incidence θᵢ₂ is greater than the critical angle for the boundary between the top surface B11 and the surrounding gas (or other medium with low index of refraction) and total internal reflection with angle of reflection θᵣ₂ happens. Due to the wedge structure of the concentrator component 31, the next angle of incidence is greater than the previous angle of incidence along the light path. Therefore, the angle of incidence is always greater than the critical angle to ensure total internal reflection. The light sequentially passes through the lateral surface B13, the gap 300 and the top surface B21 with refraction and then enters the second wedged concentrator component 32.

In this embodiment, total internal reflection happens once before the light enters the second wedged concentrator component 32. However, the times of the total internal reflection are not limited. If the initial angle of incidence θᵢ₁ is smaller or the angle θ_{B} between the lateral surface B13 and the bottom surface B12 is greater, the times increase. Alternatively, if the diffractive optics element B120 may cause greater θ_{d1}, the initial angle of incidence θᵢ₁ is greater or the angle θ_{B} is smaller, the light will directly reach the lateral surface B13 without being reflected by the top surface B11.

Please refer to FIG. 3C, a top view of the photovoltaic module 30 of FIG. 3A, illustrating the light path in the second wedged concentrator component 32. The light with angle of incidence θᵢ₃ reaches the bottom surface B22. In this embodiment, most of the light emitted to the bottom surface B22 is diffracted by the diffractive optics element B220 with angle larger than the angle of reflection. That is, the diffractive optics element B220 such as periodic grating structure can increase the angle of reflection. For example, a portion of the light is sent back to the top surface B21 with an angle θ_{d2} deviating from the normal to the bottom surface B22. The angle θ_{d2} is greater than the angle of incidence θᵢ₃. The light reaches the top surface B21 with an angle of incidence θᵢ₄. In this embodiment, the angle of incidence θᵢ₄ is greater than the critical angle for the boundary between the top surface B21 and the surrounding gas, and total internal reflection with angle of reflection θᵣ₄ happens. After several total internal reflections, the light is successfully collected to the lateral surface B23 so that the solar cell structure 35 may receives the most light photons.

In this embodiment, total internal reflection happens once before the light is received by the solar cell structure 35. However, since the light passes the top surface B21 from different directions, i.e. the angle of incidence θᵢ₃ varies, the design of the diffractive optics element B220 may be changed to modify the angle θ_{d2}. Alternatively, the design of the angle θ_{B} may be adjusted to increase or reduce the times of the total internal reflections within the second wedged concentrator component 32.

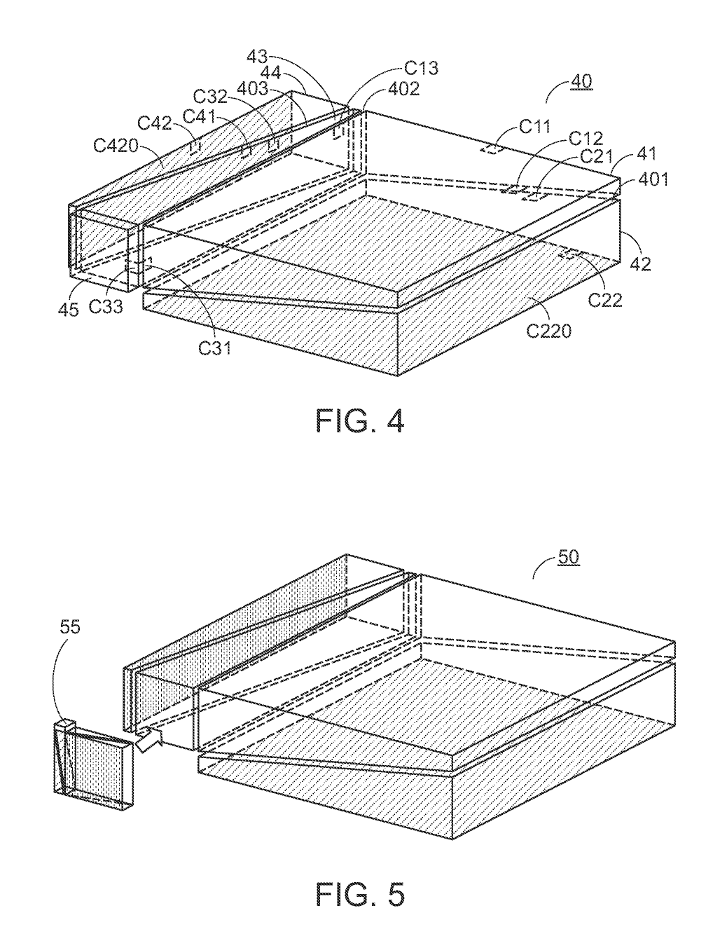

Please refer to FIG. 4, a perspective view illustrating a third embodiment of a photovoltaic module according to the present invention. The photovoltaic module 40 includes four wedged concentrator components 41, 42, 43 and 44. In this embodiment, the wedged concentrator components 41, 42, 43 and 44 include unparallel surfaces C11 and C12, C21 and C22, C31 and C32, and C41 and C42, respectively. The first wedged concentrator component 41 is positioned on the second wedged concentrator component 42 by placing the surface C12 on the surface C21. The third wedged concentrator component 43 is laid on one lateral side and positioned beside the first wedged concentrator component 41, and the surface C31 is made to be adjacent to a quadrilateral lateral surface C13 of the first wedged concentrator component 31. The fourth wedged concentrator component 44 is laid on one lateral side and positioned beside the third wedged concentrator component 43 and the surface C41 is made to be adjacent to the surface C32 of the third wedged concentrator component 43. There are gaps 401, 402 and 403 formed between the surfaces C12 and C21, surfaces C13 and C31, and surfaces C41 and C32, respectively. A solar cell structure 45 is mounted on a quadrilateral lateral surface C33 of the third wedged concentrator component 43. Two diffractive optics elements C220 and C420 are disposed on the surfaces C22 and C42, respectively.

This embodiment combines the designs of the first embodiment and the second embodiment of the photovoltaic modules 20 and 30. Concretely, the combination of the first wedged concentrator component 41 and the second wedged concentrator component 42 has the same operation principle as the combination of the first wedged concentrator component 21 and the second wedged concentrator component 22 in the first embodiment, so does the combination of the third wedged concentrator component 43 and the fourth wedged concentrator component 44. Furthermore, the combination of the first wedged concentrator component 41 and the third wedged concentrator component 43 has the same operation principle as the combination of the first wedged concentrator component 31 and the second wedged concentrator component 32 in the second embodiment. In conclusion, the light passes the four wedged concentrator components 41, 42, 43 and 44 with refraction, diffraction, and total internal reflection to reach the solar cell structure 45 and achieve the light-collecting purpose.

The third embodiment may be further modified by adding wedged concentrator components. Please refer to FIG. 5 illustrating a modified photovoltaic module 50. A small scale photovoltaic module with similar structure of the photovoltaic module 40 is provided. That is, the small scale photovoltaic module has four wedged concentrator components arranged in the above-described manner. The small scale photovoltaic module is attached to the quadrilateral lateral surface C33 of the third wedged concentrator component 43 of the large size photovoltaic module 40. Compared with the photovoltaic module 40 in the third embodiment, the modified photovoltaic module 50 has better concentrating effect so that a more compact solar cell structure 55 is employed. Hence, fewer solar cells are required in the solar cell structure 55 and the cost thereof can be further reduced.

In conclusion, the photovoltaic modules according to the present invention take advantage of wedged concentrator components and diffractive optics elements to change the light path to enhance the concentrating effect. The enhancement also improves the total conversion efficiency. Furthermore, the photovoltaic modules according to the present invention significantly reduce the thickness and the size thereof and it is not necessary to mount the solar cells to face toward the sunlight by changing the light path. The quantity of the solar cells may be reduced because the required effective receiving area for the sunlight is not as large as that of the conventional photovoltaic module. Contrary to the prior arts, the photovoltaic module according to the present invention may transmit incident light with a great range of incident angles to the solar cell structure without tracking the sun. Therefore, the photovoltaic module has better performance concerning size, cost and conversion efficiency.

While the invention has been described in terms of what is presently considered to be the most practical and preferred embodiments, it is to be understood that the invention needs not to be limited to the disclosed embodiment. On the contrary, it is intended to cover various modifications and similar arrangements included within the spirit and scope of the appended claims which are to be accorded with the broadest interpretation so as to encompass all such modifications and similar structures.

What is claimed is:

1. A photovoltaic module, comprising:
a first wedged concentrator component having a first top surface and a first bottom surface arranged unparallel with each other;
a second wedged concentrator component having a second top surface and a second bottom surface arranged unparallel with each other, the first wedged concentrator component being positioned on the second wedged concentrator component by placing the first bottom surface on the second top surface;
a solar cell structure mounted on a quadrilateral lateral surface of the first wedged concentrator component for receiving light from the first wedged concentrator component through the quadrilateral lateral surface,
wherein the light enters and leaves the first wedged concentrator component through the first top surface and the first bottom surface, respectively, enters and leaves the second wedged concentrator component through the second top surface, further enters the first wedged concentrator component through the first bottom surface, and leaves the first wedged concentrator component through the quadrilateral lateral surface in sequence, wherein total internal reflection occurs on at least the first top surface when the light travels within the first wedged concentrator component from the first bottom surface to the quadrilateral lateral surface.

2. The photovoltaic module according to claim 1 wherein a gap is formed between the first bottom surface and the second top surface, and the gap is filled with a medium with an index of refraction less than the index of refraction of the first and the second wedged concentrator components.

3. The photovoltaic module according to claim 1 wherein a diffractive optics element is disposed on the second bottom surface to increase the angle of the incidence when the light leaves the second wedged concentrator component.

4. The photovoltaic module according to claim 1 wherein an anti-reflective film is applied to the outside of the first top surface for reducing reflection of the light when the light enters the first wedged concentrator component through the first top surface.

5. The photovoltaic module according to claim 1 wherein an angle between the quadrilateral lateral surface and the first bottom surface is an acute angle.

6. The photovoltaic module according to claim 1 wherein the solar cell structure comprises at least one solar cell for performing photovoltaic conversion.

7. A photovoltaic module, comprising:
a first wedged concentrator component having a first top surface and a first bottom surface arranged unparallel with each other;
a second wedged concentrator component having a second top surface and a second bottom surface arranged unparallel with each other, the second top surface being adjacent to a first quadrilateral lateral surface of the first wedged concentrator component;
a solar cell structure mounted on a second quadrilateral lateral surface of the second wedged concentrator component for receiving light from the second wedged concentrator component through the second quadrilateral lateral surface thereof,
wherein the light enters and leaves the first wedged concentrator component through the first top surface and the first quadrilateral lateral surface, respectively, and enters and leaves the second wedged concentrator component through the second top surface and the second quadrilateral lateral surface, respectively.

8. The photovoltaic module according to claim 7 wherein a gap is formed between the first quadrilateral lateral surface and the second top surface, and the gap is filled with a medium with an index of refraction less than the index of refraction of the first and the second wedged concentrator components.

9. The photovoltaic module according to claim 7 wherein a first diffractive optics element is disposed on the first bottom surface to increase an angle between the light path and the normal to the first bottom surface.

10. The photovoltaic module according to claim 7 wherein a second diffractive optics element is disposed on the second bottom surface to increase an angle between the light path and the normal to the second bottom surface.

11. The photovoltaic module according to claim 7 wherein an anti-reflective film is applied to the outside of the first top surface for reducing reflection of the light when the light enters the first wedged concentrator component through the first top surface.

12. The photovoltaic module according to claim 7 wherein an angle between the first quadrilateral lateral surface and the first bottom surface is an acute angle.

13. The photovoltaic module according to claim 7 wherein an angle between the second quadrilateral lateral surface and the second top surface is an acute angle.

14. The photovoltaic module according to claim 7 wherein the solar cell structure comprises at least one solar cell for performing photovoltaic conversion.

15. A photovoltaic module, comprising:
a first wedged concentrator component having a first top surface and a first bottom surface arranged unparallel with each other;
a second wedged concentrator component having a second top surface and a second bottom surface arranged unparallel with each other, the first wedged concentrator component being positioned on the second wedged concentrator component by placing the first bottom surface on the second top surface;
a third wedged concentrator component having a third top surface and a third bottom surface arranged unparallel with each other, the third top surface being adjacent to a first quadrilateral lateral surface of the first wedged concentrator component;
a fourth wedged concentrator component having a fourth top surface and a fourth bottom surface arranged unparallel with each other, the fourth top surface being adjacent to the third bottom surface;
a solar cell structure mounted on a second quadrilateral lateral surface of the third wedged concentrator component for receiving light from the third wedged concentrator component through the second quadrilateral lateral surface,
wherein the light enters and leaves the first wedged concentrator component through the first top surface and the first bottom surface, respectively, enters and leaves the second wedged concentrator component through the second top surface, enters and leaves the first wedged concentrator component through the first bottom surface and the first quadrilateral lateral surface, respectively, enters and leaves the third wedged concentrator component through the third top surface and the third bottom surface, respectively, enters and leaves the fourth wedged concentrator component through the fourth top surface, and enters and leaves the third wedged concentrator component through the third bottom surface and the second quadrilateral lateral surface in sequence, wherein total internal reflection occurs on at least the first top surface and the third top surface when the light travels within the first wedged concentrator component from the first bottom surface to the first quadrilateral lateral surface and travels within the third wedged concentrator component form the third bottom surface to the second quadrilateral lateral surface.
